(19) United States
(12) Patent Application Publication
(10) Pub. No.: US 2018/0127875 A1
(43) Pub. Date: May 10, 2018

(54) APPARATUS FOR PERFORMING SELENIZATION AND SULFURIZATION PROCESS ON GLASS SUBSTRATE

(71) Applicant: NATIONAL CHUNG SHAN INSTITUTE OF SCIENCE AND TECHNOLOGY, TAOYUAN CITY (TW)

(72) Inventors: WEN-CHUEH PAN, TAOYUAN CITY (TW); JEN-CHIEH LI, TAOYUAN CITY (TW); MING-JUNE LIN, TAOYUAN CITY (TW); TIEN-FU WU, TAOYUAN CITY (TW); TSAN-TUNG CHEN, TAOYUAN CITY (TW); YIH-HSING WANG, TAOYUAN CITY (TW); SHIH-SHAN WEI, TAOYUAN CITY (TW)

(21) Appl. No.: 15/344,374

(22) Filed: Nov. 4, 2016

(51) Int. Cl. C23C 16/455; C23C 16/30; C23C 16/52; C23C 16/46

(52) U.S. Cl. CPC C23C 16/45523; C23C 16/30; C23C 16/45512; H01L 31/03923; C23C 16/52; C23C 16/46; C23C 16/45593

(57) ABSTRACT

An apparatus for performing a selenization and sulfurization process on a glass substrate is introduced. A low-cost, non-toxic selenization and sulfurization process is performed on a large-area glass substrate in a normal-pressure environment with the apparatus to turn element selenium or sulfur into small molecules of high activity at high temperature by pyrolysis or by plasma, especially linear atmospheric pressure plasma. The process is finalized by dispersing the selenium or sulfur molecules uniformly and allowing the glass substrate to undergo reciprocating motion precisely, thereby achieving large-area, uniform selenization and sulfurization of the one-piece glass substrate.

### FIELD OF THE INVENTION

The present invention relates to apparatuses for performing a selenization and sulfurization process on a glass substrate and, more particularly, to an apparatus for performing a low-cost, non-toxic selenization and sulfurization process on a large-area glass substrate in a normal-pressure environment.

### BACKGROUND OF THE INVENTION

A solar cell with a copper indium gallium selenium (Cu/In/Ga/Se, CIGS) thin-film is made of direct-bandgap semiconductor materials with bandgaps of 1.04 eV to 1.68 eV, and has advantages, such as a high optical absorption coefficient, a wide optical absorption range, high long-term illumination stability, low material and manufacturing costs, and high efficiency of conversion. Hence, the CIGS solar cell is presently promising.

One of the ways to increase the conversion efficiency of the CIGS solar cell is to increase the bandgap of a CIGS semiconductor. In general, the bandgap of the CIGS semiconductor can be increased by increasing the ratio of element gallium to elements copper, indium, gallium and selenium or substituting element sulfur for a part of element selenium. The technique of substituting element sulfur for a part of element selenium is generally known as sulfurization. The technique of performing selenization and then performing sulfurization is known as sulfurization after selenization (SAS) and entails performing sulfurization on a substrate at high temperature to not only substitute element selenium for element sulfur on the surface of the CIGS thin-film, but also allow element gallium to separate from element molybdenum and diffuse to the surface of the thin-film, and in consequence the CIGS thin-film has a dual-segment bandgap, thereby enhancing the conversion efficiency of the CIGS thin-film solar cell.

In this regard, the major technology used by the CIGS solar cell industry is usually a vacuum process, including techniques like sputtering selenization and multi-source co-evaporation, but sputtering selenization prevails. Sputtering selenization is of two types. The first type of sputtering selenization involves introducing H₂Se into a high-temperature furnace in airtight vacuum to perform high-temperature selenization, placing multiple substrates in the high-temperature furnace in a single instance when a precursor layer is already present on the surfaces of the substrate, and performing a cyclical process which include steps like vacuum creating, ventilation, heating, temperature holding, cooling, and exhausting. The first type of sputtering selenization not only takes much time, say 10 hours, to perform, but is also disadvantaged by the fact that the multi-piece process is unlikely to attain uniformity but is predisposed overly great power consumption and material loss, and thus high production costs. The second type of sputtering selenization requires rapid thermal processing (RTP) and basically includes two categories. The first category entails depositing a selenium thin-film on a substrate to function as part of a precursor layer and then effectuating rapid selenization by performing a continuous process of heating/temperature holding/cooling and internal delivery, or effectuating rapid selenization by performing a process of heating/temperature holding/cooling in an openable/insulating continuous chamber. The second category features an optional selenium thin-film precursor layer on the condition that selenization is performed among small molecules of selenium vapor which is highly active but free of toxic selenized substances.

Producing copper indium gallium selenium sulfur (CIGSS) thin-film solar cells on sodium glass substrates, using vacuum sputtering technique or electroplating technique to produce CIG (copper indium gallium) precursors in conjunction with RTP (U.S. Pat. No. 5,578,503) process—preparing a CIGSS absorption layer (U.S. Pat. No. 8,741,685B2) by selenium/sulfurization has advantages, namely high quality, high speed, and application to large-area production. RTP selenization process design varies, depending on the crystal arrangement (amorphous versus polycrystalline) of the Cu—In—Ga precursor film, the interlayer stress (tensile stress versus compressive stress), and design structure (single layer versus multi-layer), and must give considerations to the following key factors: (1) selenium/sulfurization temperature; (2) the speed of heating and cooling; (3) selenium/sulfurization duration and distribution of temperature at different stages; (4) selenium/sulfur cracking module design; (5) high temperature uniformity design; (6) chamber airtightness and station change design; (7) selenium/sulfur atmosphere uniform distribution; and (8) selenium/sulfur pollution prevention and recycling mechanism. The RTP selenization process effectuates rapid selenization in a selenium atmosphere or effectuates rapid selenization in a selenium atmosphere in the presence of a selenium evaporation precursor.

Although the techniques and methods of producing CIGS solar cells abound, the prior art provides no process that meets the demand for cost efficiency and the need for high efficiency simultaneously. The main hindrance to the development of the wanted process is that stable, large-area CIGS solar cell process technology remains undeveloped. Major issues about apparatuses for use with the process include: a lack of uniformity in the heat radiation which occurs as a result of performing the process on a large-area glass substrate, uniform distribution of selenium vapor, selenium vapor recycling, and the deformation of the glass substrate undergoing a high-temperature process. U.S. Pat. No. 5,578,503 discloses performing a process in an environment where the temperature is increased by at least 10° C. per second to preclude non-uniformity in surface tension of thin-film surface which might otherwise be caused by liquidation of element selenium in the course of selenization and thereby prevent solar cell conversion efficiency deterioration which might otherwise be caused by poor crystallization. However, performing a process on a large-area glass substrate at a temperature which is increased by at least 10° C. per second often causes the glass substrate to shatter. US2010/0226629A1 discloses a method of preventing selenium contamination in a continuous process of mass production of selenization, but US2010/0226629A1 fails to provide a solution to recycling selenium and ensuring uniform distribution of heat. U.S. Pat. No. 8,741,685B2 is directed to sulfurization and selenization of electrodeposited CIGS films by thermal annealing, and discloses forming a precursor layer by electroplating, depositing selenium or sulfur, and perforing annealing during the RTP process, and thus selenization or sulfurization is not performed in a toxic sulfurized selenium or sulfurized hydrogen environment. Nonetheless, U.S. Pat. No. 8,741,685B2 has the following disadvantages: in the liquid stage of film annealing, the non-uniformity of tension leads to uniform distribution of the ingredients of reactants; in the course of selenization, due to inadequate activity of selenium molecules, reactions taking place at the bottom layer is likely to be incomplete, thereby ending up with selenization non-uniformity and formation of small crystals. To achieve uniformity, the selenization duration has to extend to the detriment of rapid selenization, rendering selenization slow.

### SUMMARY OF THE INVENTION

In view of the aforesaid drawbacks of the prior art, it is necessary to provide an apparatus for performing a selenization and sulfurization process on a glass substrate, so as to overcome the aforesaid drawbacks of the prior art.

It is an objective of the present invention to provide an apparatus for performing a selenization and sulfurization process on a glass substrate, performing the rapid uniform heating of a one-piece glass substrate, so as to perform the rapid annealing and uniform selenization and sulfurization of a thin-film on the glass substrate.

Another objective of the present invention is to provide an apparatus for performing a selenization and sulfurization process on a glass substrate, involving pyrolysis of selenium, plasma cracking of selenium, or a combination thereof, mixing an inert gas, and performing rapid selenization and sulfurization process on the glass substrate at a substantially atmospheric pressure, so as to effectuate a selenization or sulfurization process in the presence of toxic H₂Se or H₂S rather than in a vacuum environment.

Yet another objective of the present invention is to provide an apparatus for performing a selenization and sulfurization process on a glass substrate whose temperature is raised rapidly and maintained uniformly such that selenization precedes or follows sulfurization.

Still another objective of the present invention is to provide an apparatus for performing a selenization and sulfurization process on a glass substrate and thereby recycle and reuse excess selenium vapor or sulfur produced during the process, thereby cutting material costs.

In order to achieve the above and other objectives, the present invention provides an apparatus for performing a selenization and sulfurization process on a glass substrate, comprising a first chamber, a first delivering heating module, a first heating component, and a second heating component, and further comprising a second chamber, a second delivering heating module, a third heating component, a fourth heating component, a first gas uniform distribution module, a first gas-recycling module, a first chamber communication-channel, a first temperature-measuring device, a selenium vapor generator, a selenium vapor heating component, a linear atmospheric pressure plasma cracking selenium module, a third chamber, a third delivering heating module, a fifth heating component, a sixth heating component, a second gas uniform distribution module, a second gas-recycling module, a second chamber communication-channel, a second temperature-measuring device, a sulfur generator, and a sulfur heating component. The first chamber has a first gate and a second gate. The first and second gates are disposed on two unconnected sides of the first chamber, respectively. The first delivering heating module is disposed in the first chamber and between the first gate-valve and the second gate-valve. The first heating component is disposed in the first chamber and above the first delivering module. The second heating component is disposed in the first chamber and below the first delivering module. Reflecting bowls for thermal radiation are disposed on two lateral sides of the outlet and inlet of the first chamber to enhance the heating of the border of the glass substrate. The second chamber has a fourth gate. The fourth gate is disposed on one side of the second chamber and is in communication with the first chamber. The second chamber has a third gate. The third gate is disposed on the other side of the second chamber and is in communication with a feed carrier. The second delivering heating module is disposed in the second chamber and between the third gate and the fourth gate. The third heating component is disposed in the second chamber and above the second delivering module. The fourth heating component is disposed in the second chamber and below the second delivering module. The first gas uniform distribution module is connected to the second chamber to introduce a gas into the second chamber. The second gas-recycling module is connected to the second chamber to recycle the gas in the second chamber. The first chamber communication-channel is connected to a first gate of the first chamber and a fourth gate of the second chamber. The first chamber communication-channel has a first temperature-measuring device disposed in the chamber communication-channel to measure the temperature of the passing glass substrate. The third chamber has a fifth gate. The fifth gate is disposed on one side of the third chamber and is in communication with the first chamber. The third chamber has a sixth gate. The third chamber is disposed on the other side of the third chamber. When necessary, the third chamber is connected to the other chambers for use in the selenization or sulfurization of the glass substrate. The third delivering heating module is disposed in the third chamber and between the fifth gate and the sixth gate. The fifth heating component is disposed in the second chamber and above the second delivering module. The sixth heating component is disposed in the second chamber and below the second delivering module. The second gas uniform distribution module is connected to the third chamber to introduce a gas into the second chamber. The second gas-recycling module is connected to the third chamber to recycle the gas in the third chamber. The second chamber communication-channel is connected to the second gate of the first chamber and the fifth gate of the third chamber. The chamber second communication-channel has a second temperature-measuring device disposed in the second chamber communication-channel to measure the temperature of the passing glass substrate.

In an embodiment of the present invention, the first delivering heating module has a plurality of first heating rollers each having therein a first roller heating unit.

In an embodiment of the present invention, the first heating rollers are made of graphite, silicon dioxide ceramic, zirconium oxide ceramic, quartz, or Inconel.

In an embodiment of the present invention, the second delivering heating module has a plurality of second heating rollers each having therein a second roller heating unit.

In an embodiment of the present invention, the second heating rollers are made of graphite, silicon dioxide ceramic, zirconium oxide ceramic, quartz, or Inconel.

In an embodiment of the present invention, the third delivering heating module has a plurality of third heating rollers each having therein a third roller heating unit.

In an embodiment of the present invention, the third heating rollers are made of graphite, silicon dioxide ceramic, zirconium oxide ceramic, quartz, or Inconel.

In an embodiment of the present invention, the first gas uniform distribution module comprises a first vapor producing unit, a first inert gas control unit, a first gas-mixing unit, a first mix gas heating cracking unit, and a first mix gas distribution unit. The first vapor producing unit heats up solid selenium to produce gaseous selenium molecules and controls the amount of the produced selenium vapor by temperature regulation. The first inert gas control unit outputs an inert gas and controls the amount of the output inert gas. The first gas-mixing unit is connected to the first vapor producing unit and the first inert gas control unit to mix the selenium vapor produced from the first vapor producing unit and the inert gas output from the first inert gas control unit and output a mix gas. The first mix gas heating cracking unit is connected to the first gas-mixing unit to heat the mix gas and thus produce a mix gas containing the selenium vapor which has undergone high-temperature cracking. The first mix gas distribution unit is connected to the gas heating cracking unit and the second chamber to uniform distribute the mix gas output from the mix gas heating cracking unit across the glass substrate in the second chamber.

In an embodiment of the present invention, the first mix gas heating cracking unit of the first gas uniform distribution module is a mix gas selenium vapor cracking linear atmospheric pressure plasma unit. The mix gas selenium vapor cracking linear atmospheric pressure plasma unit is connected to the first gas-mixing unit, integrated with the first mix gas distribution unit, and connected to the second chamber, and uniformly distributes the mix gas output from the mix gas selenium vapor linear atmospheric pressure plasma cracking unit across the glass substrate in the second chamber.

In an embodiment of the present invention, the second gas uniform distribution module comprises a second vapor producing unit, a second inert gas control unit, a second gas-mixing unit, a second mix gas heating cracking unit, and a second mix gas distribution unit. The second vapor producing unit heats up solid sulfur to produce gaseous sulfur molecules and controls the amount of the produced sulfur by temperature regulation. The second inert gas control unit outputs an inert gas and controls the amount of the output inert gas. The second gas-mixing unit is connected to the second vapor producing unit and the second inert gas control unit to mix the sulfur produced from the second vapor producing unit and the inert gas output from the second inert gas control unit and then output a mix gas. The second mix gas heating cracking unit is connected to the second gas-mixing unit to heat up the mix gas and thus produce a mix gas containing the sulfur which has undergone high-temperature cracking. The second mix gas distribution unit is connected to the gas heating cracking unit and the third chamber to uniformly distribute the mix gas output from the second mix gas heating cracking unit across the glass substrate in the third chamber.

In an embodiment of the present invention, the first gas-recycling module comprises a first gas-absorbing unit, a first condensing unit, and a first collecting unit. The first gas-absorbing unit is connected to the second chamber through a gas-absorbing passage to draw out of the second chamber the mix gas which contains the selenium vapor and the inert gas. The first condensing unit is connected to the first gas-absorbing unit to separate the selenium vapor and the inert gas which are drawn out with the first gas-absorbing unit. The first collecting unit is connected to the first condensing unit to collect the separated selenium vapor and inert gas.

In an embodiment of the present invention, the second gas-recycling module comprises a second gas-absorbing unit, a second condensing unit, and a second collecting unit. The second gas-absorbing unit is connected to the third chamber through a gas-absorbing passage to draw out of the third chamber a mix gas which contains sulfur and an inert gas. The second condensing unit is connected to the second gas-absorbing unit to separate the sulfur and inert gas which are drawn out of the second gas-absorbing unit. The second collecting unit is connected to the second condensing unit to collect the separated sulfur and inert gas.

In an embodiment of the present invention, the first heating component comprises a plurality of heating tubes.

In an embodiment of the present invention, the heating tubes are halogen lamps.

In an embodiment of the present invention, the second heating component comprises a plurality of heating tubes and a plurality of heat distribution plates.

In an embodiment of the present invention, the third heating component comprises a plurality of heating tubes and a plurality of heat distribution plates.

In an embodiment of the present invention, the fourth heating component comprises a plurality of heating tubes and a plurality of heat distribution plates.

In an embodiment of the present invention, the fifth heating component comprises a plurality of heating tubes and a plurality of heat distribution plates.

In an embodiment of the present invention, the apparatus for performing a selenization and sulfurization process on a glass substrate further comprises a first thermal insulation pad disposed on the inner wall of the first chamber.

In an embodiment of the present invention, the apparatus for performing a selenization and sulfurization process on a glass substrate further comprises a second thermal insulation pad disposed on the inner wall of the second chamber.

In an embodiment of the present invention, the apparatus for performing a selenization and sulfurization process on a glass substrate further comprises a third thermal insulation pad disposed on the inner wall of the third chamber.

In an embodiment of the present invention, the first temperature-measuring device is a non-contact temperature-measuring device.

In an embodiment of the present invention, the second temperature-measuring device is a non-contact temperature-measuring device.

In an embodiment of the present invention, the first chamber communication-channel provides communication between the second chamber and the first chamber and further has a first gate-valve; and the second chamber communication-channel provides communication between the third chamber and the first chamber and has a second gate-valve.

Therefore, the present invention provides an apparatus for performing a selenization and sulfurization process on a glass substrate, characterized in that: a glass substrate is rapidly heated up to undergo selenization and sulfurization in three chambers, respectively, to not only prevent the glass substrate from staying at a temperature above the softening point, but also increase the thin-film selenium/sulfurization temperature in accordance with the process requirements and thus speed up temperature holding selenium/sulfurization, thereby saving energy and saving time; with the glass substrate undergoing reciprocating motion within the chambers, there is uniform distribution of temperature across the glass substrate; furthermore, recycled selenium/sulfur and inert gas can be reused, thereby cutting material costs.

The summary above, the detailed description below, and the accompanying drawings are intended to further explain the techniques and means adopted by the present invention to achive predetermined objectives thereof as well as the benefits of the present invention. The other objectives and advantages of the present invention are depicted with the accompanying drawings and described below.

### BRIEF DESCRIPTION OF THE DRAWINGS

FIG. 1 is a schematic view of an RTP device according to an embodiment of the present invention;

FIG. 2 is a schematic view of a selenization temperature holding device according to an embodiment of the present invention;

FIG. 3 is a function block diagram of a first gas uniform distribution module according to an embodiment of the present invention;

FIG. 4 is a schematic view of a linear atmospheric pressure plasma generator and a gas uniform distribution module which are integrated with each other according to an embodiment of the present invention;

FIG. 5 is a schematic view of a first mix gas distribution unit according to an embodiment of the present invention;

FIG. 6 is a function block diagram of a first gas-recycling module according to an embodiment of the present invention;

FIG. 7 is a schematic view of a sulfurization temperature holding device according to an embodiment of the present invention;

FIG. 8 is a function block diagram of a second gas uniform distribution module according to an embodiment of the present invention;

FIG. 9 is a schematic view of a second mix gas distribution unit according to an embodiment of the present invention;

FIG. 10 is a function block diagram of a second gas-recycling module according to an embodiment of the present invention; and

FIG. 11 is a schematic view of an apparatus for performing a selenization and sulfurization process on a glass substrate according to an embodiment of the present invention.

### DETAILED DESCRIPTION OF THE PREFERRED EMBODIMENTS

The implementation of the present invention is hereunder illustrated with specific embodiments so that persons skilled in the art can gain insight into the other advantages and benefits of the present invention easily by referring to the disclosure contained in the specification of the present invention.

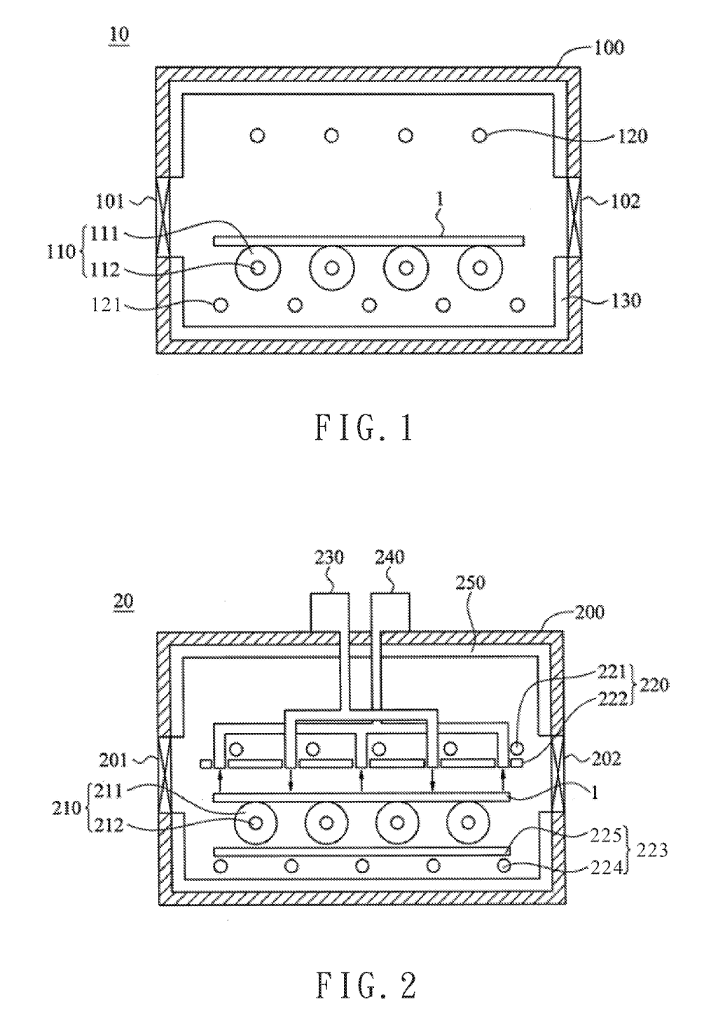

Referring to FIG. 1, there is shown a schematic view of a rapid thermal processing (RTP) device 10 according to an embodiment of the present invention. The RTP device 10 performs uniform, rapid heating on a glass substrate 1 to raise the temperature thereof by, say, 10° C. per second, and enables the glass substrate 1 to change station rapidly and undergo reciprocating motion rapidly. The RTP device 10 has a first chamber 100, a first delivering heating module 110, a first heating component 120, a second heating component 121, and two lateral tube units or reflecting bowl units (not shown).

The first chamber 100 has a first gate 101 and a second gate 102 which can be movably opened or shut. The first gate 101 and the second gate 102 are disposed on two unconnected lateral sides of the first chamber 100, respectively. The first delivering heating module 110 is disposed in the first chamber 100. The first delivering heating module 110 is disposed between the first gate 101 and the second gate 102.

During the process, the RTP device 10 operates in a vacuum state with a vacuum pump (not shown) so as to be insulated from the outside and create an airtight space defined by the first chamber 100, the first gate 101 and the second gate 102. The vacuum state is a low vacuum state. The glass substrate 1 is introduced into or removed from the first chamber 100 through the first gate 101 and the second gate 102.

During the process, the glass substrate 1 is placed on the first delivering heating module 110. The first delivering heating module 110 drives the glass substrate 1 to undergo reciprocating motion. The first delivering heating module 110 has a plurality of first heating rollers 111. The first heating rollers 111 each have therein a first roller heating unit 112. The first roller heating units 112 heat up the first heating rollers 111. By heating up the first heating rollers 111 uniformly, the temperature of the contact surfaces of the glass substrate 1 and each first heating roller 111 and the temperature of the glass substrate 1 are kept within a specific temperature range. Furthermore, the first heating rollers 111 are made of a material resistant to high-temperature selenium sulfurization, such as graphite, silicon dioxide ceramic, zirconium oxide ceramic, quartz, or Inconel. The outer surfaces of the first heating rollers 111 are made of a plasma deposited ceramic membrane to increase their surface friction coefficient and maintain a low thermal conductivity coefficient.

The first heating component 120, second heating component 121, and two lateral tube units or reflecting bowls (not shown) heat up the glass substrate 1 and a CIGS thin-film (not shown) disposed on the upper surface of the glass substrate 1. In this embodiment, the first heating component, second heating component and lateral heating components can be heating tubes, electrical heating tubes, or heating plates. The heating tubes can be halogen lamps having a higher heating speed. The present invention selectively uses specific halogen lamps operating at a wavelength which matches the wavelength of the heat absorbed by the CIGS thin-film disposed on the upper surface of the glass substrate 1, so as to increase the heating efficiency. Due to the heat dissipation which occurs at the border of the glass substrate 1, during the rapid heating process that takes place at a high temperature, the difference in temperature between the border of the glass substrate 1 and the center of the glass substrates 1 is likely to exceed 10° C. to the detriment of the uniformity of the two thin-films. Hence, the heating components or reflecting bowls are disposed at the two lateral sides of the glass substrate 1 to enhance the efficiency of raising the temperature at the border of the glass substrate 1.

To keep the heat inside the first chamber 100 and thus maintain the temperature therein, a first thermal insulation pad 130 (such as a graphite felt) is disposed on the inner wall of the first chamber 100.

Referring to FIG. 2, there is shown a schematic view of a selenization temperature holding device 20 according to an embodiment of the present invention. The selenization temperature holding device 20 performs a uniform selenization process on the glass substrate 1 to thereby provide a device for use in high-temperature temperature holding selenization of the glass substrate 1, and enable the glass substrate 1 to change station rapidly and undergo reciprocating motion rapidly. The selenization temperature holding device 20 comprises a second chamber 200, a second delivering heating module 210, a third heating component 220, a fourth heating component 223, a first gas uniform distribution module 230, and a first gas-recycling module 240.

The second chamber 200 has a third gate 201 which can be movably opened or shut and a fourth gate 202 optionally provided as needed. The second delivering heating module 210 is disposed in the second chamber 200. The second delivering heating module 210 is disposed between the third gate 201 and the fourth gate 202. The third heating component 220 is disposed in the second chamber 200. The third heating component 220 is disposed above the glass substrate 1. The third heating component 220 comprises a heating tube 221 and a heat distribution plate 222, wherein the heating tube is a halogen lamp. The heat distribution plate 222 is made of a material that conducts heat rapidly, such as graphite. The heat distribution plate 222 takes in the heat radiated from the heating tube, rapidly absorbs the heat, and uniformly distributes the heat across the glass substrate 1 by radiation. The fourth heating component 223 is disposed in the second chamber 200. The fourth heating component 223 is disposed below the glass substrate 1. The fourth heating component 223 comprises a heating tube 224 and a heat distribution plate 225, wherein the heating tube is a halogen lamp. The heat distribution plate 225 is made of a material that conducts heat rapidly, such as graphite. The heat distribution plate 225 takes in the heat radiated from the heating tube, rapidly absorbs the heat, and uniformly distributes the heat across the glass substrate 1 by radiation. To eliminate the non-uniform heat distribution otherwise caused by rapid heat dissipation at the border of the glass substrate 1, it is necessary that, among the tube, the heat distribution plate, and the glass substrate 1 aligned in a direction (perpendicular to the advancing direction of the glass substrate 1), the tube is of a larger length than the heat distribution plate, and the heat distribution plate is of a larger length than the glass substrate 1.

To keep the heat inside the second chamber 200 and thus maintain the temperature therein, a second thermal insulation pad 250 (such as a graphite felt) is disposed on the inner wall of the second chamber 200.

During the process, like the RTP device 10, the selenization temperature holding device 20 is insulated from the outside by the second chamber 200, the third gate 201, and the fourth gate 202 to create an airtight space in a low vacuum state. The glass substrate 1 is moved into the second chamber 200 or moved out of the second chamber 200 through the third gate 201 and the fourth gate 202.

During the process, the glass substrate 1 is disposed on the second delivering heating module 210 such that the second delivering heating module 210 drives the glass substrate 1 to undergo reciprocating motion. Like the first delivering heating module 110, the second delivering heating module 210 has a plurality of second heating rollers 211 each having therein a second roller heating unit 212. Furthermore, the second heating rollers 211 are made of a material resistant to high-temperature selenization, such as graphite, silicon dioxide ceramic, zirconium oxide ceramic, quartz, or Inconel. The outer surfaces of the second heating rollers 211 are made of a plasma deposited ceramic membrane to increase their surface friction coefficient and maintain a low thermal conductivity coefficient.

The third heating component 220 heats up the glass substrate 1 and a CIGS thin-film (not shown) disposed on the upper surface of the glass substrate 1. The third heating component 220 comprises a plurality of heating tubes 221 and a plurality of heat distribution plates 222, wherein the heating tubes are halogen lamps. The heating tubes 221 heat up the heat distribution plates 222 to a temperature required for the process. Furthermore, a reflecting bowl (not shown) is disposed on a lateral side of the second chamber 200 for containing the glass substrate 1, so as to compensate for a lower border temperature. The heat distribution plates 222 in the second chamber 200 each have a plurality of openings serving as entrances and exits for a gas of the first gas uniform distribution module 230 and the first gas-recycling module 240.

The fourth heating component 223 is disposed below the glass substrate 1 to heat up the glass substrate 1. The fourth heating component 223 comprises a plurality of heating tubes 224 and a plurality of heat distribution plates 225, wherein the heating tubes are halogen lamps. The heating tubes 224 heat up the heat distribution plates 225 to a temperature required for the process and thus transfer the heat to the glass substrate 1 by radiation.

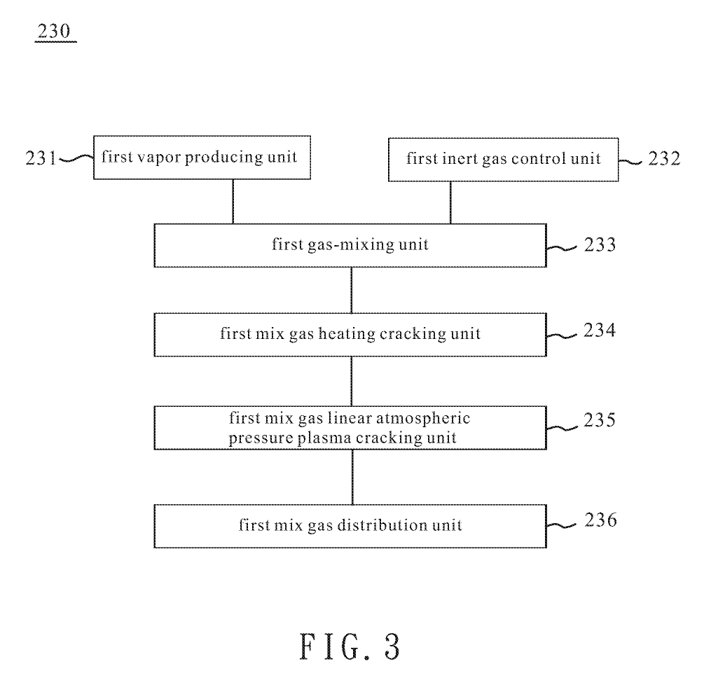

Referring to FIG. 3, there is shown a function block diagram of a first gas uniform distribution module 230 according to an embodiment of the present invention. The first gas uniform distribution module 230 comprises a first vapor producing unit 231, a first inert gas control unit 232, a first gas-mixing unit 233, a first mix gas heating cracking unit 234, a first mix gas linear atmospheric pressure plasma cracking unit 235, and a first mix gas distribution unit 236.

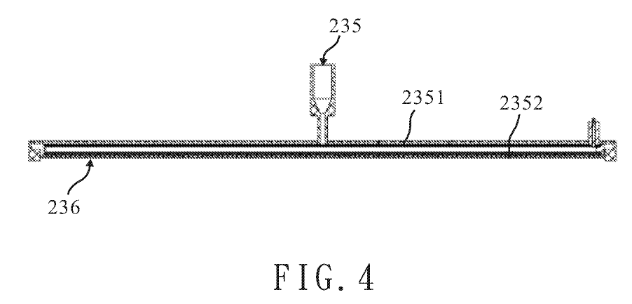

The first vapor producing unit 231 heats up solid selenium to produce gaseous selenium molecules during the selenization process, and controls the amount of the produced selenium vapor by temperature regulation. The first inert gas control unit 232 outputs an inert gas and controls the amount of the output inert gas by pressure regulation and flow rate regulation. The first gas-mixing unit 233 is connected to the first vapor producing unit 231 and the first inert gas control unit 232 to mix the selenium vapor produced from the first vapor producing unit 231 and the inert gas output from the first inert gas control unit 232 and output a mix gas. The first mix gas heating cracking unit 234 is connected to the first gas-mixing unit 233 to heat up the mix gas, produce a mix gas which contains a selenium vapor which has undergone high-temperature cracking, and control the flow rate of the selenium vapor which eventually enters the chambers by regulating the pressure and flow rate of the inert gas, the amount of the produced selenium vapor, and the environment pressure of the second chamber 20. Unlike a conventional selenization process, the present invention is characterized by substituting cracking selenium that mixes with an inert gas at a substantially atmospheric pressure for performing toxic selenization of H₂Se in vacuum, so as to render the process operation safe. In this embodiment, the mix gas produced from the first gas-mixing unit 233 passes through the first mix gas heating cracking unit 234, then passes through the first mix gas linear atmospheric pressure plasma cracking unit 235, and finally passes through the first mix gas distribution unit 236. Referring to FIG. 4, the first mix gas cracking linear atmospheric pressure plasma unit is connected to the first mix gas heating cracking unit 234 and integrated with the first mix gas distribution unit. The first mix gas linear atmospheric pressure plasma cracking unit 235 comprises an electrode 2351 required for production of plasma and a plurality of openings 2352 required for uniform distribution of gas, and is connected to the second chamber, to distribute uniformly the mix gas output from the first mix gas linear atmospheric pressure plasma cracking unit across the glass substrate 1 in the second chamber. The first mix gas heating cracking unit of the first gas uniform distribution module is a mix gas selenium vapor cracking linear atmospheric pressure plasma unit. The shape and size of the openings of the first mix gas distribution unit 236 are determined by CFD computation and analysis such that the gas distribution perpendicular to the motion direction of the glass substrate 1 meets the process requirements.

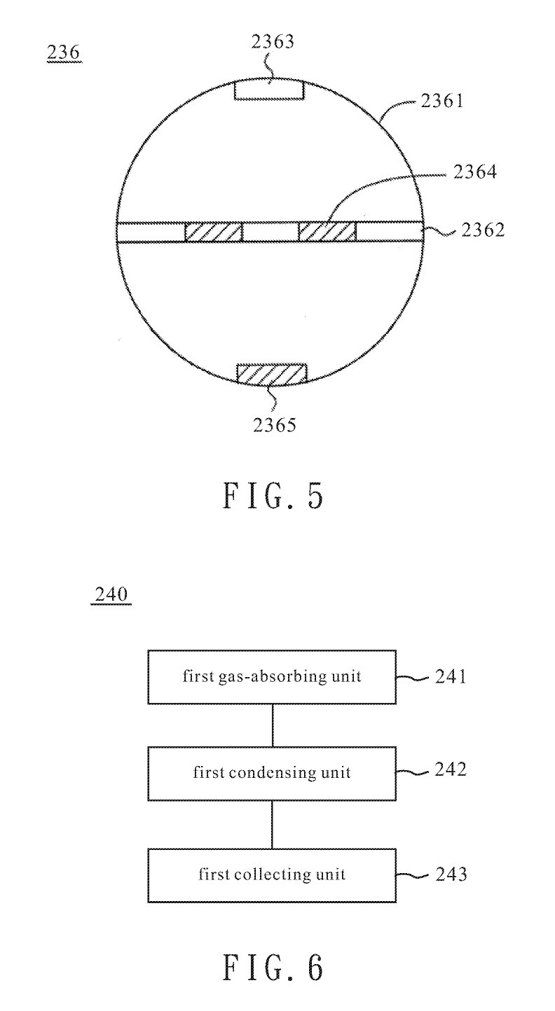

Referring to FIG. 5, there is shown a schematic view of the first mix gas distribution unit 236 according to another embodiment of the present invention. The first mix gas distribution unit 236 comprises a round pipe 2361 and a panel 2362. A main aperture 2363 is disposed on the upper end of the round pipe 2361 and connected to the first mix gas heating cracking unit 234. A plurality of emission holes 2365 is disposed at the lower end of the round pipe 2361. The panel 2362 is disposed in the round pipe 2361 and has a plurality of through-holes 2364. With the through-holes 2364 and the emission holes 2365, the first mix gas distribution unit 236 allows a mix gas of the selenium vapor and the inert gas to be uniformly distributed across the glass substrate 1. In a variant embodiment, the first mix gas distribution unit 236 is formed by coupling together a half-cut round pipe 2361 and a panel 2362.

Referring to FIG. 6, there is shown a function block diagram of a first gas-recycling module 240 according to an embodiment of the present invention. The first gas-recycling module 240 comprises a first gas-absorbing unit 241, a first condensing unit 242, and a first collecting unit 243.

The first gas-absorbing unit 241 is connected to the second chamber 200 through a gas-absorbing passage (not shown) to draw excess selenium vapor and inert gas out of the second chamber 200 during the process. The first condensing unit 242 is connected to the first gas-absorbing unit 241 such that the selenium vapor absorbed by the first gas-absorbing unit 241 is condensed with the first condensing unit 242 and thus cured such that the solid selenium and the gaseous inert gas are recycled by a gas-solid phase separation mechanism. The first collecting unit 243 is connected to the first condensing unit 242 to collect the separated solid selenium and gaseous inert gas so as to reuse the recycled solid selenium and gaseous inert gas, thereby cutting material costs.

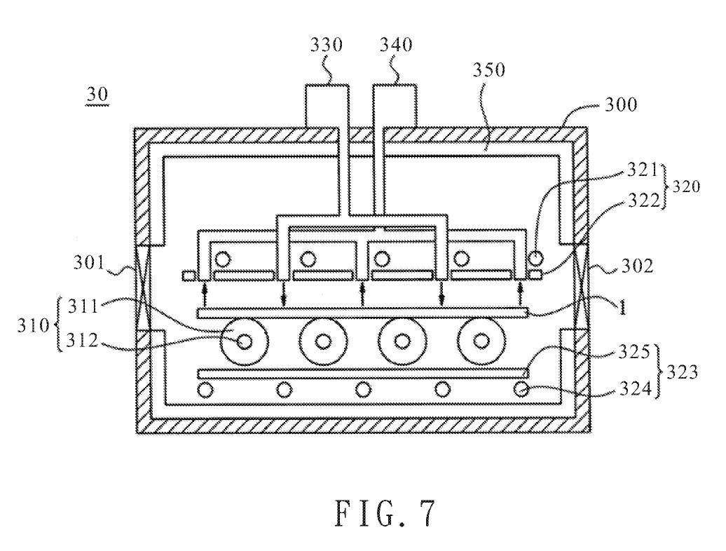

Referring to FIG. 7, there is shown a schematic view of a sulfurization temperature holding device 30 according to an embodiment of the present invention. The sulfurization temperature holding device 30 performs a uniform sulfurization process on the glass substrate 1 to thereby provide a device for use in high-temperature temperature holding sulfurization of the glass substrate 1, and enable the glass substrate 1 to change station rapidly and undergo reciprocating motion rapidly. The sulfurization temperature holding device 30 comprises a third chamber 300, a third delivering heating module 310, a fifth heating component 320, a sixth heating component 323, a second gas uniform distribution module 330, and a second gas-recycling module 340.

The third chamber 300 has a sixth gate 302 which can be movably opened or shut and a fifth gate 301 optionally provided as needed. The third delivering heating module 310 is disposed in the third chamber 300. The third delivering heating module 310 is disposed between the fifth gate 301 and the sixth gate 302. The fifth heating component 320 is disposed in the third chamber 300. The fifth heating component 320 is disposed above the glass substrate 1. The fifth heating component 320 comprises a heating tube 321 and a heat distribution plate 322, wherein the heating tube is a halogen lamps. The heat distribution plate 322 is made of a material that conducts heat rapidly, such as graphite. The heat distribution plate 322 takes in the heat radiated from the heating tube, rapidly absorbs the heat, and uniformly distributes the heat across the glass substrate 1 by radiation. The sixth heating component 323 is disposed in the third chamber 300. The sixth heating component 323 is disposed below the glass substrate 1. The sixth heating component 323 comprises a heating tube 324 and a heat distribution plate 325. The heat distribution plate 325 is made of a material that conducts heat rapidly, such as graphite. The heat distribution plate 325 takes in the heat radiated from the heating tube, rapidly absorbs the heat, and uniformly distributes the heat across the glass substrate 1 by radiation. To eliminate the non-uniform heat distribution otherwise caused by rapid heat dissipation at the border of the glass substrate 1, it is necessary that, among the tube, the heat distribution plate, and the glass substrate 1 aligned in a direction (perpendicular to the advancing direction of the glass substrate 1), the tube is of a larger length than the heat distribution plate, and the heat distribution plate is of a larger length than the glass substrate 1.

To keep the heat inside the third chamber 300 and thus maintain the temperature therein, a third thermal insulation pad 350 (such as a graphite felt) is disposed on the inner wall of the third chamber 300.

During the process, like the RTP device 10, the sulfurization temperature holding device 30 is insulated from the outside by the third chamber 300, the fifth gate 301 and the sixth gate 302 to create an airtight space in a low vacuum state. The glass substrate 1 is moved into the third chamber 300 or moved out of the third chamber 300 through the fifth gate 301 and the sixth gate 302.

During the process, the glass substrate 1 is placed on the third delivering heating module 310 such that the third delivering heating module 310 drives the glass substrate 1 to undergo reciprocating motion. Like the first delivering heating module 110, the third delivering heating module 310 has a plurality of third heating rollers 311. Each third heating roller 311 has therein a third roller heating unit 312. Furthermore, the third heating rollers 311 are made of a material resistant to high-temperature selenization, such as graphite, silicon dioxide ceramic, zirconium oxide ceramic, quartz, or Inconel. The outer surfaces of the third heating rollers 311 are made of a plasma deposited ceramic membrane to increase their surface friction coefficient and maintain a low thermal conductivity coefficient.

The fifth heating component 320 heats up the glass substrate 1 and a CIGS thin-film (not shown) on the upper surface of the glass substrate 1. The fifth heating component 320 comprises a plurality of heating tubes 321 and a plurality of heat distribution plates 322, wherein the heating tubes are halogen lamps. The heating tubes 321 heat up the heat distribution plates 322 to a temperature required for the process. Furthermore, reflecting bowls (not shown) are disposed on the lateral sides of the third chamber 300 which holds the glass substrate 1 to compensate for the lower temperature at the border of the glass substrate 1. A plurality of openings is disposed at the heat distribution plates 322 to serve as entrances and exits for the gas of the second gas uniform distribution module 330 and the second gas-recycling module 340.

The sixth heating component 323 is disposed below the glass substrate 1 to heat up the glass substrate 1. The sixth heating component 323 comprises a plurality of heating tubes 324 and a plurality of heat distribution plates 325, wherein the heating tubes are halogen lamps. The heating tubes 324 heat up the heat distribution plates 325 to a temperature required for the process and thus transfer the heat to the glass substrate 1 by radiation.

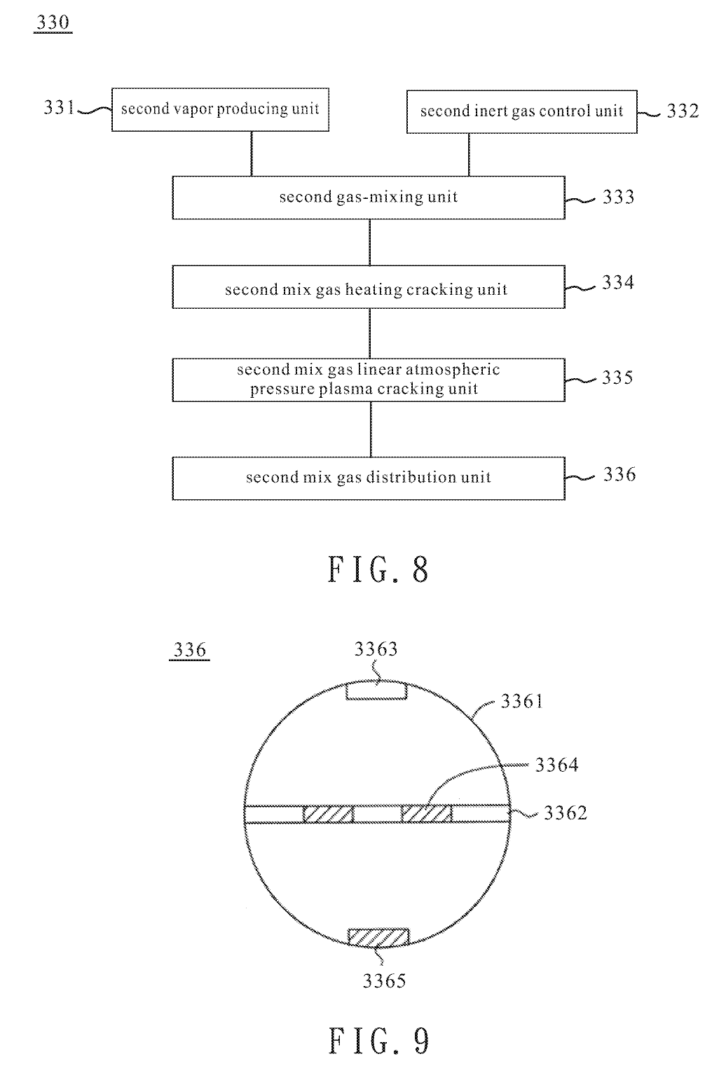

Referring to FIG. 8, there is shown a function block diagram of a second gas uniform distribution module 330 according to an embodiment of the present invention. The second gas uniform distribution module 330 comprises a second vapor producing unit 331, a second inert gas control unit 332, a second gas-mixing unit 333, a second mix gas heating cracking unit 334, a second mix gas linear atmospheric pressure plasma cracking unit 335, and a second mix gas distribution unit 336.

The second vapor producing unit 331 heats up solid sulfur to produce gaseous sulfur molecules during the sulfurization process, and controls the amount of the produced sulfur by temperature regulation. The second inert gas control unit 332 outputs an inert gas and controls the amount of the output inert gas by pressure regulation and flow rate regulation. The second gas-mixing unit 333 is connected to the second vapor producing unit 331 and the second inert gas control unit 332 to mix the sulfur produced from the second vapor producing unit 331 and the inert gas output from the second inert gas control unit 332 and output a mix gas. The second mix gas heating cracking unit 334 is connected to the second gas-mixing unit 333 to heat up the mix gas, produce a mix gas which contains sulfur that has undergone high-temperature cracking, and control the flow rate of the sulfur which eventually flows into the chambers by regulating the pressure and flow rate of the inert gas, the amount of the sulfur produced, and the environment pressure in the third chamber 30. Unlike a conventional sulfurization process, the present invention is characterized by substituting cracking sulfur that mixes with an inert gas at a substantially atmospheric pressure for performing toxic sulfurization of H₂S in vacuum, so as to render the process operation safe. In this embodiment, the mix gas produced from the second gas-mixing unit 333 passes through the second mix gas heating cracking unit 334, then passes through the second mix gas linear atmospheric pressure plasma cracking unit 335, and finally passes through the second mix gas distribution unit 336. Referring to FIG. 8, the sulfur in the mix gas output from the second mix gas distribution unit 336 undergoes cracking, and then the mix gas is uniformly distributed across the glass substrate 1 in the third chamber connected to the second mix gas distribution unit 336. The shape and size of the openings of the second mix gas distribution unit 336 are determined by CFD computation and analysis such that the gas distribution perpendicular to the motion direction of the glass substrate 1 meets the process requirements.

Referring to FIG. 9, there is shown a schematic view of the second mix gas distribution unit 336 according to another embodiment of the present invention. The second mix gas distribution unit 336 comprises a round pipe 3361 and a panel 3362. The upper end of the round pipe 3361 has a main aperture 3363 for connection with the second mix gas heating cracking unit 334. A plurality of emission holes 2365 is disposed at the lower end of the round pipe 3361. The panel 3362 is disposed in the round pipe 3361. A plurality of through-holes 3364 is disposed at the panel 3362. With the through-holes 3364 and the emission holes 3365, the second mix gas distribution unit 336 allows the mix gas of the sulfur vapor and the inert gas to be uniformly distributed across the glass substrate 1. In a variant embodiment, the second mix gas distribution unit 336 is formed by coupling together a half-cut round pipe 3361 and a panel 3362.

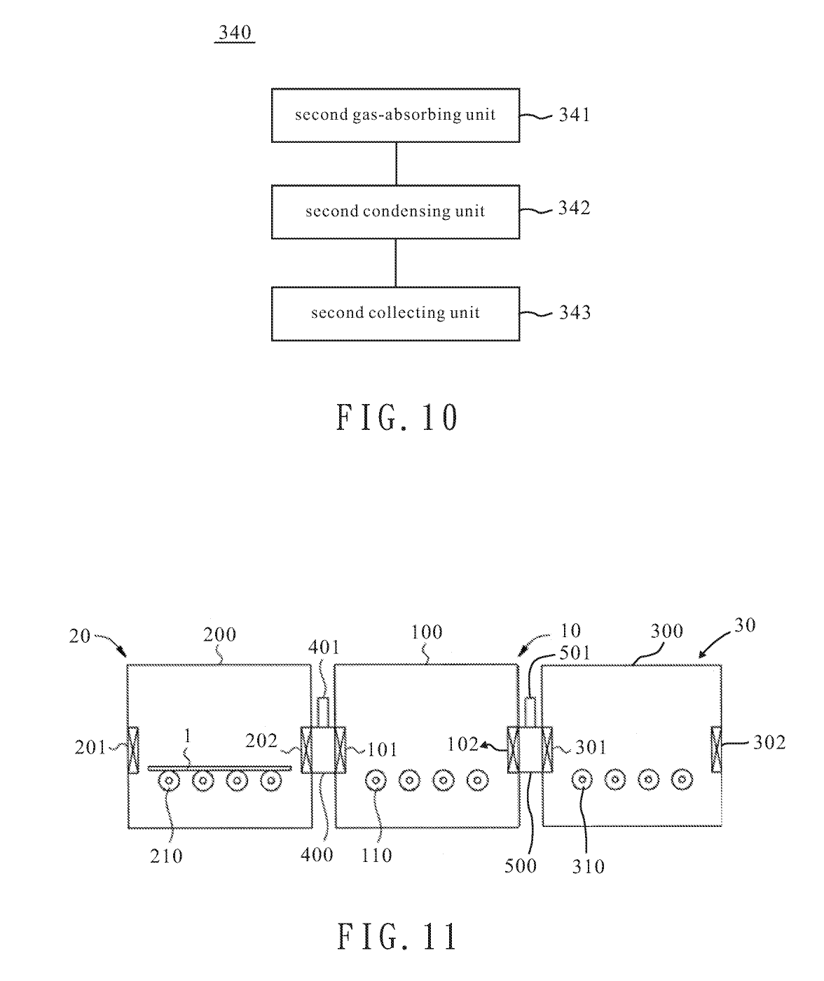

Referring to FIG. 10, there is shown a function block diagram of a second gas-recycling module 340 according to an embodiment of the present invention. The second gas-recycling module 340 comprises a second gas-absorbing unit 341, a second condensing unit 342, and a second collecting unit 343.

The second gas-absorbing unit 341 is connected to the third chamber 300 through a gas-absorbing passage (not shown) to draw excess sulfur and inert gas out of the third chamber 300 in the process. The second condensing unit 342 is connected to the second gas-absorbing unit 341. The sulfur drawn out with the second gas-absorbing unit 341 is condensed with the second condensing unit 242 and thus cured such that the solid sulfur and the gaseous inert gas are recycled by a gas-solid phase separation mechanism. The second collecting unit 343 is connected to the second condensing unit 342 to collect the separated solid sulfur and gaseous inert gas such that the solid sulfur and gaseous inert gas are recycled and reused, thereby cutting material costs.

Referring to FIG. 11, there is shown a schematic view of an apparatus for performing a selenization and sulfurization process on the glass substrate 1 according to an embodiment of the present invention, showing how the RTP device and the selenization and sulfurization temperature holding devices are coupled together. To show how the RTP device 10 and the selenization and sulfurization temperature holding devices 20, 30 are coupled together, FIG. 11 shows only part of the related components. For details of the arrangement of related components, see FIG. 1 through FIG. 10.

Referring to FIG. 11, in an embodiment of the present invention, the first chamber 100 and the second chamber 200 are connected by a first chamber communication-channel 400. The two ends of the chamber communication-channel 400 are connected to the first gate 101 of the first chamber 100 and the fourth gate 202 of the second chamber 200, respectively. A temperature-measuring device 401 is disposed on the chamber communication-channel 400. The temperature-measuring device 401 is a non-contact temperature-measuring device. The temperature-measuring device 401 measures the real-time temperature of the thin-film skimming the glass substrate 1 in the chamber communication-channel 400.

The selenium sulfurization process of the present invention is exemplified by a process described below. The first-stage selenization temperature (such as 350° C.)→the second-stage selenization temperature (such as 550° C.)→the third-stage sulfurization temperature (such as 600° C.) are achieved in the steps described as follows: deliver the glass substrate 1 into the first chamber 100 through the second chamber 200; introduce the glass substrate 1 into the first chamber 100 through the second delivering heating module 210 and the first delivering heating module 110; shut the first through sixth gates 101, 102, 201, 202, 301 and 302; start a vacuum gas-drawing system (such as a vacuum pump), and start heating systems (for example, the first delivering heating module 110, first heating component 120, and second heating component 121 shown in FIG. 1, the second delivering heating module 210, third heating component 220, and fourth heating component 221 shown in FIG. 2, and the third delivering heating module 310, fifth heating component 320, and sixth heating component 321 shown in FIG. 3) of the first chamber 100, second chamber 200 and third chamber 300, respectively, as soon as the inside of the first chamber 100 and the inside of the second chamber 200 reach a low vacuum state (such as 10-2 torr). When the glass substrate 1 is placed on the first delivering heating module 110 in the first chamber 100 of low vacuum, the first heating rollers 111 are heated up by the first roller heating units 112 disposed therein, whereas the first heating component 120 and the second heating component 121 heat up the glass substrate 1 rapidly; meanwhile, the second heating component 121 disposed below the first delivering heating module 110 heats up the first heating rollers 111 to therefore keep the difference between the surface temperature of the first heating rollers 111 and the temperature of the glass substrate 1 within a specific temperature range.

At this point in time, the heat distribution plates 222 are heated up by the heating tube 221 of the third heating component 220 of the second chamber 200, and the second heating rollers 211 are heated up by the second roller heating units 212 therein, wherein the heat distribution plates 222 and the second heating rollers 211 are heated up by the heating tubes 225 of the fourth heating component 223 below the second delivering heating modules 210, to keep the difference between the surface temperature of the second heating rollers 211 and the temperature of the glass substrate 1 within a specific temperature range; meanwhile, the heating system of the third chamber heats up the heat distribution plates 222 and the second heating rollers 211 until their temperature reaches a predetermined sulfurization temperature.

After the glass substrate 1 in the first chamber 100 has been heated up to a specific temperature, the first gate 101 of the first chamber 100 and the fourth gate 202 of the second chamber 200 start such that the temperature of the first delivering heating module 110 in the first chamber 100, the second delivering heating module 210 and the glass substrate 1 in the second chamber 200, and the heat distribution plates 222, 224 in the second chamber 200 falls within a specific temperature range. Afterward, the first delivering heating module 110 in the first chamber 100 rapidly delivers the glass substrate 1 into the second chamber 200 through the first chamber communication-channel 400; meanwhile, the non-contact temperature-measuring device 401 disposed on the first chamber communication-channel measures the temperature of the glass substrate 1. The second delivering heating module 210 of the second chamber 200 carries the glass substrate 1 such that the glass substrate 1 undergoes reciprocating motion within the second chamber 200. After the glass substrate 1 has been delivered to the second chamber 200, the first gate 101 of the first chamber 100 and the fourth gate 202 of the second chamber 200 are shut to create an airtight space in the first chamber 100 and an airtight space in the second chamber 200. The temperature holding selenization process that takes place in the second chamber 200 entails distributing the mix gas which consists of a selenium vapor and an inert gas across the glass substrate 1 uniformly with the first gas uniform distribution module 230 and performing a selenization reaction at a high temperature with a thin-film on the glass substrate 1 to form a CIGS thin-film.

The scenario where the process involves multiple stages of selenium sulfurization is described below. After the glass substrate 1 has undergone a first-stage selenization reaction in the second chamber 200, the glass substrate 1 is returned to the first chamber 100 in the aforesaid manner to undergo a second-stage continuous RTP operation. Afterward, the glass substrate 1 has its temperature measured with the non-contact temperature-measuring device 401 disposed at the first chamber communication-channel 400 while the glass substrate 1 is passing through the first communication-channel 400. At this point in time, the heat distribution plates of the second chamber are continuously heated up until they reach a predetermined temperature required for the second-stage temperature holding; meanwhile, the first chamber 100 heats up the glass substrate 1 as well such that the glass substrate 1 is delivered to the second chamber 200 as soon as the temperature required for the second-stage process is reached, so as for the glass substrate 1 to undergo a second-stage temperature holding selenization reaction. Completion of the second-stage selenization reaction is accompanied by the attainment of 600° C., i.e., the temperature at which the third-stage sulfurization is going to occur, wherein the glass substrate 1 has its temperature measured with the non-contact temperature-measuring device 401 disposed at the first chamber communication-channel 400 while the glass substrate 1 is passing through the first communication-channel 400. After the glass substrate 1 has completely entered the first chamber 100, the gates are shut. The temperature in the first chamber 100 rises rapidly to heat up the glass substrate 1 to a predetermined sulfurization temperature; meanwhile, the gates of the sulfurization chamber 30 and the gates of the selenization chamber 20 are shut such that the sulfurization chamber 30 and the selenization chamber 20 are not in communication with each other to thereby preclude cross contamination of the selenium vapor and sulfur. When the temperature of the glass substrate 1 reaches the predetermined temperature, the second gate 102 of the first chamber 100 and the fifth gate 301 of the third chamber 300 open. When glass substrate 1 passes through the second communication-channel, a non-contact temperature-measuring device 501 disposed at the second chamber communication-channel 500 measures the temperature of the glass substrate 1. After the glass substrate 1 has entered the third chamber completely, its gates are shut; meanwhile, the heat distribution plates and the heating rollers of the third chamber have reached the predetermined sulfurization temperature and begun performing the third-stage temperature holding sulfurization reaction.

Therefore, the present invention provides an apparatus for performing a selenization and sulfurization process on a glass substrate, characterized in that: a glass substrate is rapidly heated up to undergo selenization and sulfurization in three chambers, respectively, to not only prevent the glass substrate from staying at a temperature above the softening point, but also increase the thin-film selenium/sulfurization temperature in accordance with the process requirements and thus speed up temperature holding selenium/sulfurization, thereby saving energy and saving time; with the glass substrate undergoing reciprocating motion within the chambers, there is uniform distribution of temperature across the glass substrate; furthermore, recycled selenium/sulfur and inert gas can be reused, thereby cutting material costs.

Although the features and advantages of the present invention are disclosed above by preferred embodiments, the preferred embodiments are not restrictive of the present invention. Any persons skilled in the art can make some changes and modifications to the preferred embodiments without departing from the spirit and scope of the present invention. Accordingly, the legal protection for the present invention should be defined by the appended claims.

What is claimed is:

1. An apparatus for performing a selenization and sulfurization process on a glass substrate, the apparatus comprising:
a first chamber having a first gate and a second gate, with the first and second gates disposed on two unconnected sides of the first chamber, respectively;
a first delivering heating module disposed in the first chamber and between the first gate and the second gate;
a first heating component disposed in the first chamber and above the first delivering module;
a second heating component disposed in the first chamber and below the first delivering module;
a second chamber having a third gate and a fourth gate, with the third and fourth gates disposed on two sides of the second chamber, respectively;
a second delivering heating module disposed in the second chamber and between the third gate and the fourth gate;
a third heating component comprising a heating tube and a heat distribution plate and disposed in the second chamber and above the second delivering module;
a fourth heating component comprising a heating tube and a heat distribution plate and disposed in the second chamber and below the second delivering module;
a first gas uniform distribution module connected to the second chamber to introduce a gas into the second chamber;
a first gas-recycling module connected to the second chamber to recycle the gas in the second chamber;
a first chamber communication-channel connected to the first gate of the first chamber and the fourth gate of the second chamber;
a first temperature-measuring device disposed in the first chamber communication-channel;
a third chamber having a fifth gate and a sixth gate, with the fifth and sixth gates disposed on two sides of the third chamber, respectively;
a third delivering heating module disposed in the third chamber and between the fifth gate and the sixth gate;
a fifth heating component comprising a heating tube and a heat distribution plate and disposed in the third chamber and above the third delivering module;
a sixth heating component comprising a heating tube and a heat distribution plate and disposed in the third chamber and below the third delivering module;
a second gas uniform distribution module connected to the third chamber to introduce a gas into the third chamber;
a second gas-recycling module connected to the third chamber to recycle the gas in the third chamber;
a second chamber communication-channel connected to the second gate of the first chamber and the fifth gate of the third chamber; and
a second temperature-measuring device disposed in the second chamber communication-channel.

2. The apparatus for performing a selenization and sulfurization process on a glass substrate according to claim 1, wherein the first delivering heating module has a plurality of first heating rollers each having therein a first roller heating unit.

3. The apparatus for performing a selenization and sulfurization process on a glass substrate according to claim 2, wherein the first heating rollers are made of one of graphite, silicon dioxide ceramic, zirconium oxide ceramic, quartz, and Inconel.

4. The apparatus for performing a selenization and sulfurization process on a glass substrate according to claim 3, wherein outer surfaces of the first heating rollers are made of a plasma deposited ceramic membrane.

5. The apparatus for performing a selenization and sulfurization process on a glass substrate according to claim 1, wherein the second delivering heating module has a plurality of second heating rollers each having therein a second roller heating unit.

6. The apparatus for performing a selenization and sulfurization process on a glass substrate according to claim 5, wherein the second heating rollers are made of one of graphite, silicon dioxide ceramic, zirconium oxide ceramic, quartz, and Inconel.

7. The apparatus for performing a selenization and sulfurization process on a glass substrate according to claim 6, wherein outer surfaces of the second heating rollers are made of a plasma deposited ceramic membrane.

8. The apparatus for performing a selenization and sulfurization process on a glass substrate according to claim 1, wherein the third delivering heating module has a plurality of third heating rollers each having therein a third roller heating unit.

9. The apparatus for performing a selenization and sulfurization process on a glass substrate according to claim 8, wherein the third heating rollers are made of one of graphite, silicon dioxide ceramic, zirconium oxide ceramic, quartz, and Inconel.

10. The apparatus for performing a selenization and sulfurization process on a glass substrate according to claim 9, wherein outer surfaces of the third heating rollers are made of a plasma deposited ceramic membrane.

11. The apparatus for performing a selenization and sulfurization process on a glass substrate according to claim 1, wherein the first gas uniform distribution module comprises:
a first vapor producing unit which heats up solid selenium to produce gaseous selenium molecules and controls an amount of the produced selenium vapor by temperature regulation;
a first inert gas control unit for outputting an inert gas and controlling an amount of the inert gas thus output;
a first gas-mixing unit connected to the first vapor producing unit and the first inert gas control unit to mix the selenium vapor produced from the first vapor producing unit and the inert gas output from the first inert gas control unit and output a mix gas;
a first mix gas heating cracking unit connected to the first gas-mixing unit to heat the mix gas and thus produce a mix gas containing the selenium vapor which has undergone high-temperature cracking; and
a first mix gas distribution unit connected to the first gas heating cracking unit and the second chamber to uniformly distribute in the second chamber the mix gas output from the first mix gas heating cracking unit.

12. The apparatus for performing a selenization and sulfurization process on a glass substrate according to claim 11, wherein the first mix gas heating cracking unit is a first mix gas cracking linear atmospheric pressure plasma unit, the first mix gas cracking linear atmospheric pressure plasma unit being connected to the first gas-mixing unit, integrated with the first mix gas distribution unit, connected to the second chamber, and adapted to uniformly distribute a mix gas produced by the first mix gas linear atmospheric pressure plasma cracking unit across the glass substrate in the second chamber.

13. The apparatus for performing a selenization and sulfurization process on a glass substrate according to claim 1, wherein the first mix gas distribution unit comprises:
a round pipe, with a main aperture disposed on an upper end of the round pipe and connected to the first mix gas heating cracking unit, and a plurality of emission holes disposed at a lower end of the round pipe, and
a panel disposed in the round pipe and having a plurality of through-holes.

14. The apparatus for performing a selenization and sulfurization process on a glass substrate according to claim 1, wherein the first gas-recycling module comprises:
a first gas-absorbing unit connected to the second chamber through a gas-absorbing passage to draw the gas out of the second chamber;
a first condensing unit connected to the first gas-absorbing unit to separate a vapor and an inert gas which are drawn out with the first gas-absorbing unit; and
a first collecting unit connected to the first condensing unit to collect the separated vapor and inert gas.

15. The apparatus for performing a selenization and sulfurization process on a glass substrate according to claim 1, wherein the second gas uniform distribution module comprises:
a second vapor producing unit which heats up solid sulfur to produce gaseous sulfur molecules and controls an amount of the produced sulfur by temperature regulation;
a second inert gas control unit for outputting an inert gas and controlling an amount of the inert gas thus output;
a second gas-mixing unit connected to the second vapor producing unit and the second inert gas control unit to mix the sulfur produced by the second vapor producing unit and the inert gas output from the second inert gas control unit and output a mix gas;
a second mix gas heating cracking unit connected to the second gas-mixing unit to heat the mix gas and thus produce a mix gas containing the sulfur which has undergone high-temperature cracking; and
a second mix gas distribution unit connected to the second gas heating cracking unit and the second chamber to uniformly distribute in the third chamber the mix gas output from the second mix gas heating cracking unit.

16. The apparatus for performing a selenization and sulfurization process on a glass substrate according to claim 15, wherein the second mix gas heating cracking unit is a second mix gas cracking linear atmospheric pressure plasma unit, the second mix gas cracking linear atmospheric pressure plasma unit being connected to the second gas-mixing unit, integrated with the second mix gas distribution unit, connected to the third chamber, and adapted to uniformly distribute a mix gas produced by the second mix gas linear atmospheric pressure plasma cracking unit across the glass substrate in the third chamber.

17. The apparatus for performing a selenization and sulfurization process on a glass substrate according to claim 15, wherein the second mix gas distribution unit comprises:
a round pipe, with a main aperture disposed on an upper end of the round pipe and connected to the first mix gas heating cracking unit, and a plurality of emission holes disposed at a lower end of the round pipe, and
a panel disposed in the round pipe and having a plurality of through-holes.

18. The apparatus for performing a selenization and sulfurization process on a glass substrate according to claim 1, wherein the second gas-recycling module comprises:
a second gas-absorbing unit connected to the second chamber through a gas-absorbing passage to draw the gas out of the third chamber;
a second condensing unit connected to the second gas-absorbing unit to separate a vapor and an inert gas which are drawn out by the second gas-absorbing unit; and
a second collecting unit connected to the second condensing unit to collect the separated vapor and inert gas.

19. The apparatus for performing a selenization and sulfurization process on a glass substrate according to claim 1, wherein the first heating component comprises a plurality of heating tubes.

20. The apparatus for performing a selenization and sulfurization process on a glass substrate according to claim 1, wherein the second heating component comprises a plurality of heating tubes and a plurality of heat distribution plates.

21. The apparatus for performing a selenization and sulfurization process on a glass substrate according to claim 1, wherein the third heating component comprises a plurality of heating tubes and a plurality of heat distribution plates.

22. The apparatus for performing a selenization and sulfurization process on a glass substrate according to claim 1, wherein the fourth heating component comprises a plurality of heating tubes and a plurality of heat distribution plates.

23. The apparatus for performing a selenization and sulfurization process on a glass substrate according to claim 1, wherein the fifth heating component comprises a plurality of heating tubes and a plurality of heat distribution plates.

24. The apparatus for performing a selenization and sulfurization process on a glass substrate according to claim 1, further comprising a first thermal insulation pad disposed on an inner wall of the first chamber.

25. The apparatus for performing a selenization and sulfurization process on a glass substrate according to claim 1, further comprising a second thermal insulation pad disposed on an inner wall of the second chamber.

26. The apparatus for performing a selenization and sulfurization process on a glass substrate according to claim 1, further comprising a third thermal insulation pad disposed on an inner wall of the third chamber.

27. The apparatus for performing a selenization and sulfurization process on a glass substrate according to claim 1, wherein the first and second temperature-measuring devices are non-contact temperature-measuring devices.
